(19) United States
(12) Patent Application Publication
(10) Pub. No.: US 2025/0048561 A1
(43) Pub. Date: Feb. 6, 2025

(54) FIELD PROGRAMMABLE SOLDER BALL GRID ARRAY WITH EMBEDDED CONTROL SYSTEMS

(71) Applicant: Tesla, Inc., Austin, TX (US)

(72) Inventors: Vijaykumar KRITHIVASAN, Mountain View, CA (US); Jin ZHAO, San Jose, CA (US); Jianjun LI, Irvine, CA (US)

(21) Appl. No.: 18/292,867

(22) PCT Filed: Aug. 15, 2022
(86) PCT No.: PCT/US2022/040356

§ 371 Date: Jan. 26, 2024

Related U.S. Application Data
(60) Provisional application No. 63/260,374, filed on Aug. 18, 2021.

(51) Int. Cl. H05K 3/34; H05K 1/02; H05K 3/00

(52) U.S. Cl. CPC H05K 3/3494; H05K 1/0287; H05K 3/0008; H05K 3/3436; H05K 2201/09963; H05K 2201/10212; H05K 2201/10734; H05K 2203/163

(57) ABSTRACT

A field programmable solder BeTA (FPSBGA) module may be utilized to assemble PCB/Substrate in any stack-up configuration. The local field programmable soldering BGA includes control system provides the necessary feedback for effective control of thermal profiles. The FPSBGA enables a control component (110) to cause the execution of the temperature application component (120) to cause a non-uniform application of specified temperature parameters to the substrate.

### CROSS-REFERENCE TO RELATED APPLICATION

This application claims the benefit of U.S. Provisional Patent Application No. 63/260,374, titled “FIELD PROGRAMMABLE SOLDER BALL GRID ARRAY WITH EMBEDDED CONTROL SYSTEMS,” filed Aug. 18, 2021, the disclosure of which is incorporated herein by reference in its entirety and for all purposes.

### BACKGROUND

### Technical Field

The present disclosure relates generally to electronic system assemblies and in particular to control systems for utilization of field programmable solder.

### Description of the Related Technology

Electronic system assemblies can include a plurality of components such as a system on chip (SOC), an application-specific integrated circuit (ASIC), printed circuit board assembly (PCBA) etc. Such electronic system assemblies can utilize reflow solder for fixing components to substrates. Traditional convection or mass reflow will be severely limited when dealing with an array-based application, thermal mass will lower the chance of assembly significantly. There by increasing the probability of catastrophic package integrity.

### BRIEF DESCRIPTION OF THE DRAWINGS

FIG. 1 illustrates a system for implementation of programmable solder ball reflow grid array including a control system and temperature application component in accordance with aspects of the present application;

FIG. 2A and FIG. 2B are a perspective view of an example electronic system assembly including arrays of solder balls that can be utilized to generate electronic traces on the electronic system assembly;

FIG. 3 is a block diagram of an illustrative architecture for a control system for implementing programmable solder ball reflow in accordance with one or more aspects of the present application;

FIG. 4A-4D are illustrative of a substrate incorporating a trace generated in accordance with an execution program implemented by a control component in accordance with one or more aspects of the present application; and

FIG. 5 is a flow diagram illustrative of a control program implemented by a control component to cause application of a temperature application component in accordance with aspects of the present application.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

In accordance with aspects of the present application a field programmable solder BGA (FPSBGA) module may be utilized to assemble PCB/Substrate in any stack-up configuration. The control system is operable to obtain system configuration related to a reflow grid array on a substrate. The system configuration can include at least one of a specified temperature parameters for the temperature application component and at least one trace pattern for positioning of the temperature application component along the substrate in accordance with the reflow grid array. The control system can then execute a control program for causing application of the temperature application component in accordance with the at least one trace pattern. As described in detail, the application of the temperature application component in accordance with the at least one trace pattern is characterized in non-uniform application of the specified temperature parameters to the substrate. The non-uniform application can correspond to application of the specified temperature attributes to portions of the substrate, illustratively with solder balls arrays, to create the specified trace. Additionally, the non-uniform application of the specified temperature parameters can minimize or mitigate the application of increased temperatures to other portions of the substrate, such as portions for dielectric materials, mounted components (e.g., temperature sensitive components), the like.

The local field programmable soldering BGA will solve the issue by decoupling the need for global heating to localized heating. Illustratively, the incorporation of the FPSBGA creates additional space on by opening up much needed areas on the electronic system and can increase the density of the application. Illustratively, the FPSBGA also a fully integrated control system, exploiting passive/active embedding technology, embedded within the outline of module. This control system provides the necessary feedback for effective control of thermal profiles, which can be customized based on the solder material that will be used. It is targeted for an array-based application such as neural network computing or machine learning compute node application. In addition, the FPSBGA enables a vertical reflow solution, helping to increase the density of the packaging, as a result it will increase the integration density. It can also address challenges traditional reflow approach will have in terms of overall thermal mass which is hard to solve without compromising performance or lifetime reliability.

The FPSBGA and associated control systems described herein can be used to provide mass reflow solder for mounting components on an electronic system assembly. The components which can be incorporated or utilized include, but are not limited to: circuit boards (e.g., PCBAs, daughter boards, stacked PCBAs, etc.), heatsinks, busbars, metal plates, sheet metal plates, and/or other metal components.

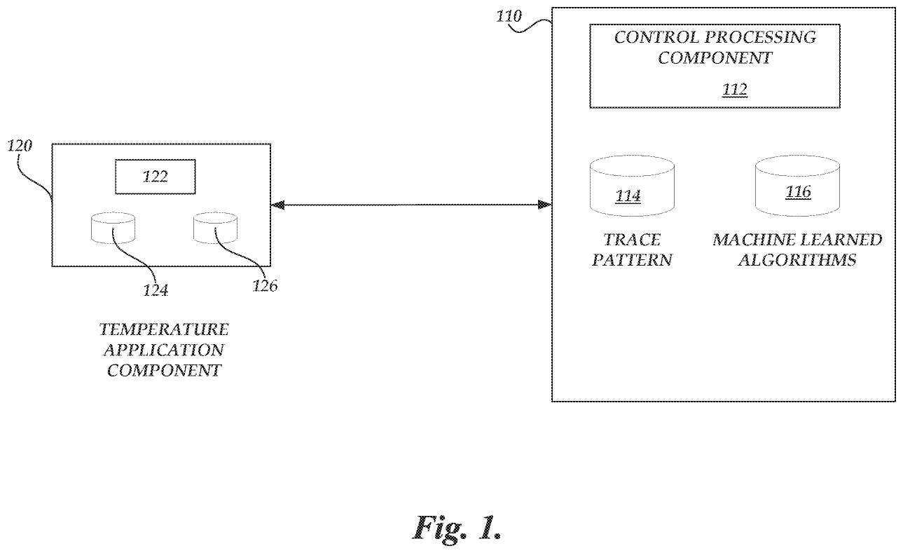

FIG. 1 illustrates a system 100 for implementation of programmable solder ball reflow grid array including a control system and temperature application component in accordance with aspects of the present application. The system 100 includes a control processing system 110 including at least one control processing component 112 for receiving configuration information related to programmable reflow on a mounted substrate. The control processing component 112 can also cause the operation of a temperature application component 120 and receive feedback regarding the achievement desired/specified temperature parameters. The control processing system 100 can include one or more data stores for implementation of the control programs. The data stores can include trace patterns data stores 114 corresponding to a specified or generated trace pattern to be implemented on the substrate. The data stores can also include one or more machine learned algorithms trained to provide control signals to the temperature application component 120, receive feedback/operation parameters regarding execution of the control signals and provide additional or updated control signals.

The system 100 further includes a temperature application control component 120 that correspond to one or more physical components for mounting a substrate and causing a localized application of a heat source 122 to at least portions of the mounted substrate. The temperature application control component 120 can correspond to any one of a variety of physical hardware and associated software components based on operating parameters, such as dimensions of the substrate, operating temperatures, power consumption, and the like. The temperature application control component 120 can receive control signals from the control processing component, including positioning information, temperature controls, duration and the like. The temperature application control component 120 can include multiple data stores 124, 126 for storing and executing received control signals and recording and storing feedback.

FIG. 1 is intended to be a logical representation of the various components/systems of the system 100. Accordingly, one skilled in the relevant art will appreciate that implementation of the individual systems or components included in the system 100 may include any number of physical devices, computing devices, communication networks and other components or physical items. Thus, FIG. 1 is intended solely for illustrative purposes.

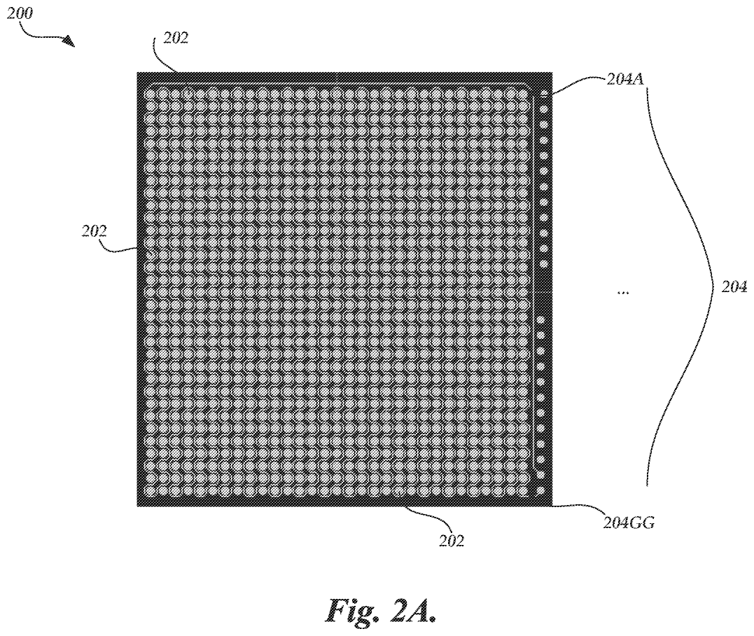

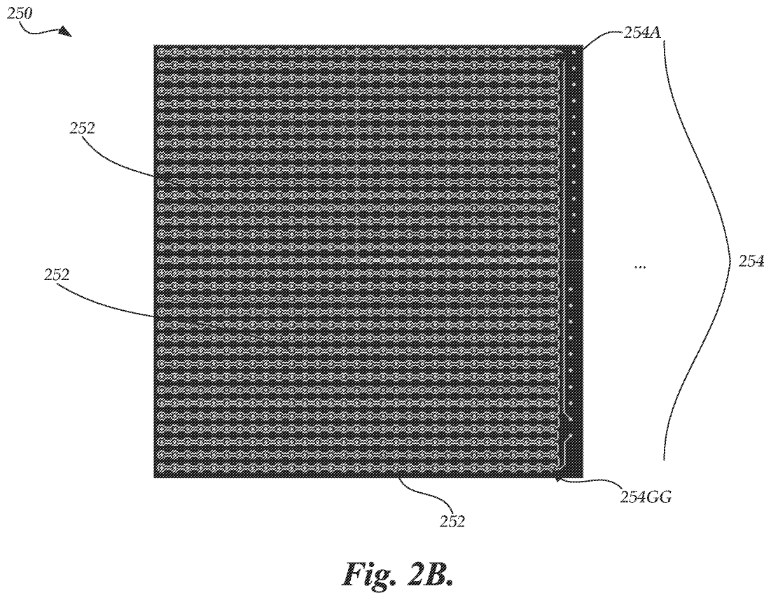

FIG. 2A and FIG. 2B are a perspective view of an example electronic system assembly including arrays of solder balls that can be utilized to generate electronic traces on the electronic system assembly. More specifically, FIG. 2A and FIG. 2B are a perspective view of an example electronic system assembly 200, 250 including arrays of solder balls 202, 252 that can be utilized to generate electronic traces on the electronic system assembly. Based on the application of a heat source, such as from the temperature application component 120, one or more of the solder balls in the arrays 202, 252 may be activated by transferring to a liquid or semi-liquid form.

Illustratively, the array of solder balls can correspond to different designs for an electronic system assembly. For example, the electronic system assembly 200 of FIG. 1A may correspond to a top layer of an electronic system assembly. The electronic system assembly 250 of FIG. 1B may correspond to an inner layer of an electronic system assembly. In an illustrative embodiment, the arrays of solder balls are formed as a matrix having 33 rows 204, 254, with each individual row having 31 solder balls. The number of rows in the array and the number of solder balls in the individual rows can vary and the illustrated electronic system assemblies 200, 250 are illustrative. As will be described in greater detail below, by the localized application of a heat source to the solder ball array 202, 252 for a specified duration, individual sets of solder balls can because to formed trace patterns along a portion of the electronic system assembly.

In an illustrative embodiment, the amount of heat required to active individual solder balls on the array can be calculated as a function of the solder materials and symmetry of the array of solder balls in one embodiment. Illustratively, the heat required to increase solder temperature is defined as:

$$H 1 = MsCp ( Tf - Ti )$$

The total heat required to melt the solder can be defined as:

$$H 2 = MsLf$$

Accordingly, the total heat required for an individual solder ball can be defined as: Hr=H1+H2

Table 1 illustrates sample current and temperature values:

TABLE 1

| | | TEMPER- | HEAT | |
|---|---|---|---|---|
| | | ATURE | CON- | HEAT |
| | CURRENT | DIFFERENCE | DUCTED | REQUIRED |
| MATERIAL | (A) | (° C.) | (J) | (J) |
| Copper | 1 | 40 | 0.152 | 0.2851 |
| Copper | 1.5 | 88 | 0.544 | 0.2851 |
| Copper | 2 | 156 | 0.9655 | 0.2851 |
| Copper | 1 | 30 | 0.1348 | 0.2851 |
| Copper | 1.5 | 67 | 0.1516 | 0.2851 |
| Copper | 2 | 120 | 0.3404 | 0.2851 |
| Copper (6 | 1.5 | 100 | 0.37 | 0.2851 |
| layers) | | | | |

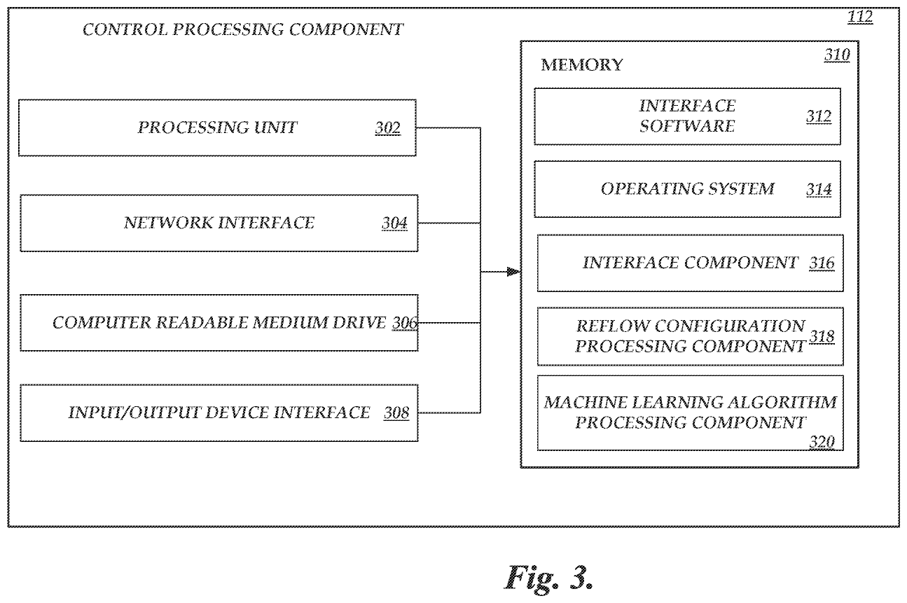

FIG. 3 is a block diagram of an illustrative architecture for a control system component 112 for implementing programmable solder ball reflow in accordance with one or more aspects of the present application. The general architecture of the control system component 112 depicted in FIG. 3 includes an arrangement of computer hardware and software components that may be used to implement aspects of the present disclosure. As illustrated, the control system component 112 may include a processing unit 302, an input/output device interface 308, a computer-readable medium 306, and a network interface 304, all of which may communicate with one another by way of a communication bus. The components of the control system component 112 may be physical hardware components or implemented in as a software module. For example, the control system component 112 may be implemented as general purpose computing device configured with the illustrated executable code to implement functionality or as a dedicated computing component.

The network interface 304 may provide connectivity to one or more networks, such as a communication network to interact with the temperature application component 120. The input/output device interface 308 can be an interface to receive or transmit signals. The computer-readable medium drive 306 can be utilized to access executable components or data. In some embodiments, the control system component 112 can include more (or fewer) components than those shown in FIG. 3.

The memory 310 may include computer program instructions that the processing unit 302 executes in order to implement one or more embodiments. The memory 310 generally includes RAM, ROM, or other persistent or non-transitory memory. The memory 310 may store interface software 312 and an operating system 314 that provides computer program instructions for use by the processing unit 302 in the general administration and operation of the control system component 112. The memory 310 may further include computer program instructions and other information for implementing aspects of the present disclosure. For example, in one embodiment, the memory 310 includes interface software 316 for transmitting control signals to the temperature application component 120 and receiving feedback/processing results regarding the application of localized energy/heat to a substrate. The memory 310 further includes a reflow configuration processing component 318 for processing configuration information correlated to a programmable solder ball reflow grid array. The configuration information can illustratively include one or more temperature parameters/attributes for the temperature application component 120 and a desired/specified trace to be generated on a mounted substrate.

The memory further includes a machine learned algorithm component 320 that corresponds to one or more machine learned algorithms for processing the temperature parameter/attributes, generated feedback/processing results and desired trace patterns and generating corresponding control signals for the temperature application component 120. Illustratively, the machine learned algorithm is generated based on training a machine learning algorithm based on training sets that correspond to processing inputs and generating outputs associated with heat application. However, by way of non-limiting examples, the machine learning algorithms can incorporate different learning models, including, but not limited to, a supervised learning model, an unsupervised learning model, a reinforcement learning model or a featured learning model. Depending on the type of learning model adopted by the machine learning algorithm, the configuration for processing with the collected individual information can vary (e.g., using a training set for a supervised or semi-supervised learning model). In other embodiments, the machine learning algorithm can implement a reinforcement-based learning model that implements a penalty/reward model implemented by the control system.

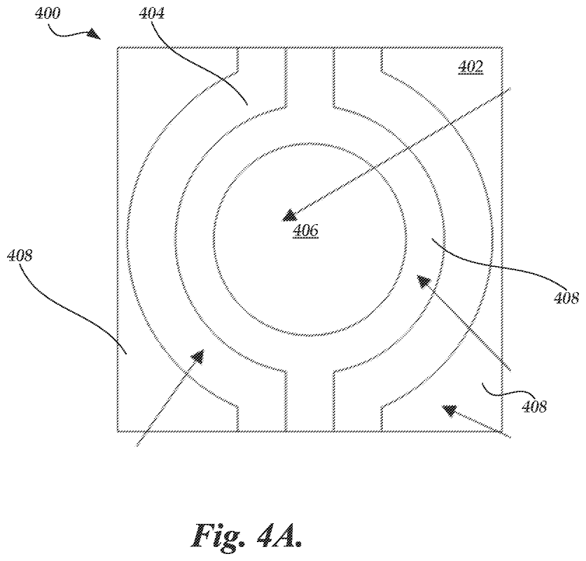

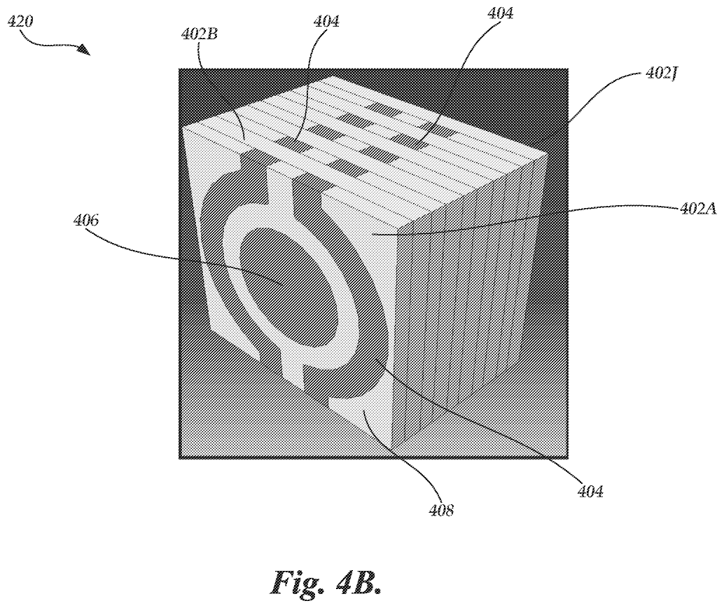

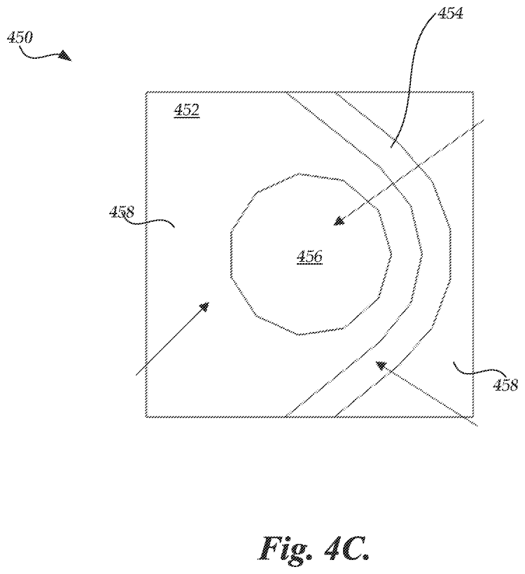

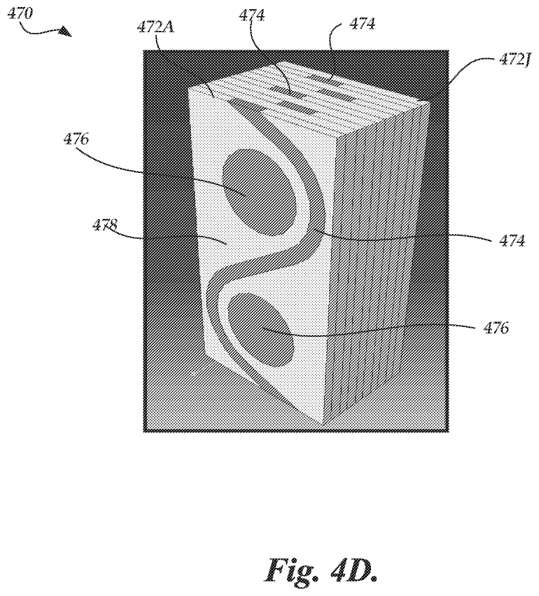

As described above, in accordance with aspects of the present application, the operation of the temperature application component 120 can be controlled such that heat can be applied to portions of a substrate in a non-uniform manner. Illustratively, the operation of the temperature application component 120 can be controlled such that specific temperature parameters can be localized to result in the one or more solder balls in an array of solder balls (as illustrated in FIG. 2A or 2B) forming traces in accordance with a desired trace pattern or otherwise being caused to become a liquid or semi-liquid in accordance with a desired pattern. FIG. 4A-4D are illustrative of a substrate incorporating a trace generated in accordance with an execution program implemented by a control component in accordance with one or more aspects of the present application.

FIGS. 4A and 4B are illustrative of a trace element that may be utilized on one or more layers of an electronic assembly. Illustratively, FIGS. 4A and 4B correspond to one or more embodiments of an electronic assembly 400 and 420 including a trace 402 that can be utilized on both side of a layer. In this embodiment, the trace element 402 is symmetrical relative to the horizontal axis of the substrate 402. FIG. 4A illustrates a single electronic assembly 400 including a single substrate 402 having the trace 404. The substrate 402 can include a copper pad 406, for a portion/region of the substrate 402 in which one or more components may be mounted. Additionally, the substrate 402 can include one or more portions or sections 408 that may be non-conductive, or substantially non-conductive, such as a dielectric material used as an insulating layer (e.g., poor conductivity). The dielectric materials can include, but are not limited to, porcelains, mica, glass, plastics, metal oxides, and the like.

FIG. 4B illustrates a multi-layered electronic assembly 420 including a plurality of substrates 422A-422J. In this embodiment, the plurality of substrates are complimentary in which every other layer does not have the trace element.

FIGS. 4C-4D are illustrative of a trace element that may be utilized on one or more layers of an electronic assembly. Illustratively, FIGS. 4C-4D corresponds to a trace that can be utilized on a single side of a layer. In this embodiment, the trace element 402 is asymmetrical relative to the horizontal axis of the substrate 452. FIG. 4C illustrates a single electronic assembly 450 including a single substrate 452 having the trace 454. The substrate 452 can include a copper pad 456, for a portion/region of the substrate 452 in which one or more components may be mounted. Additionally, the substrate 452 can include one or more portions or sections 408 that may be non-conductive, or substantially non-conductive, such as a dielectric material used as an insulating layer (e.g., poor conductivity). As described above, the dielectric materials can include, but are not limited to, porcelains, mica, glass, plastics, metal oxides, and the like.

FIG. 4B illustrates a multi-layered electronic assembly 470 including a plurality of substrates 472A-472J. In this embodiment, the plurality of substrates are complimentary in which every other layer does not have the trace element. In the substrates 472, two copper pads 476 may be implemented on the substrate 472.

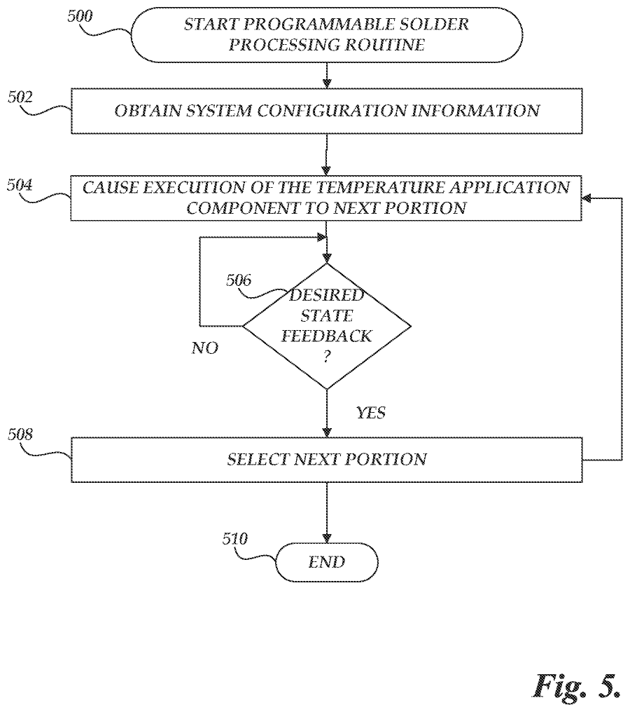

FIG. 5 is a flow diagram illustrative of a control program implemented by a control component 112 to cause application of a temperature application component 120 in accordance with aspects of the present application. At block 502, the control component 112 obtain system configuration related to a reflow grid array on a substrate. Illustratively, the system configuration including at least one of a specified temperature parameters for the temperature application component 120. The temperature parameters can include a specified temperature range that should be applied. In other embodiments, the temperature parameters can include temperature categories or levels (e.g., low, high, medium, etc.).

Additionally, the system configuration can include at least one trace pattern for positioning of the temperature application component along the substrate in accordance with the reflow grid array. The trace pattern can be specified in a variety of manners including graphical representations, reference to template designs or pre-configured shapes/patterns, coordinate descriptions, and the like.

At block 504, the control component 112 executes or causes the execution of a control program for causing application of the temperature application component in accordance with the at least one trace pattern. Illustratively, this begins with the application of temperature parameters at a first portion of the substrate. As described previously, the application of the temperature application component can be configured such that a resulting non-uniform application of the specified temperature parameters to the substrate is applied. Illustratively, the control program can include the application of the temperature application component along portions of the substrate with solder ball grid arrays for a specified time or to achieve a specified temperature range to cause the solder ball to achieve a liquid or semi-liquid phase. For example, the application of the temperature parameters can cause the formation of the trace element.

At block 506, the control component 112 can receive feedback regarding the application. If the desired temperature or resulting state is not achieved, the control component 112 will remain at the current section. Alternatively, if the desired temperature configuration has been achieved, the control component will continue to an additional or next portion in accordance with the specified pattern in the configuration component. Illustratively, one or more components or portions of the substrate may be omitted in order to achieve the non-uniform application of the temperature parameters. Once no further portions or sections are required, the control component 112 can cease sending control signals or cause the temperature application component 120 to cease operation. Accordingly, portions such as components on the copper pad(s) or portions of the dielectric materials may receive less temperature inputs from the temperature application component 120. At block 508, the routine 500 terminates.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed press-fit fastener assembly. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other. Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application.

What is claimed is:

1. A system, comprising:
a temperature application component, wherein the temperature application component is controllable in accordance with instructions related to position and temperature; and
a control unit for causing operation of the temperature application component, the control unit including computer-executable instructions that, when executed, cause the control unit to:
obtain system configuration related to a reflow grid array on a substrate, the system configuration including at least one of a specified temperature parameters for the temperature application component and at least one trace pattern for positioning of the temperature application component along the substrate in accordance with the reflow grid array; and
execute a control program for causing application of the temperature application component in accordance with the at least one trace pattern, wherein application of the temperature application component in accordance with the at least one trace pattern is characterized in non-uniform application of the specified temperature parameters to the substrate.

2. The system of claim 1, wherein the control program for causing application of the temperature application component includes at least one machine learned component for causing the application of the temperature application component according to the at least one trace pattern on the substrate.

3. The system of claim 1, wherein the at least one trace pattern corresponds to a single side of the substrate.

4. The system of claim 1, wherein the system configuration includes a reflow grid array on a plurality of substrates, wherein each individual substrate includes at least one trace pattern for positioning of the temperature application component along the substrate in accordance with the reflow grid array.

5. The system of claim 4, wherein individual trace patterns for the plurality of substrates are complimentary to adjacent substrates.

6. The system of claim 1, wherein the control unit is further operative to receive feedback regarding application of the temperature application component to designated portions of the substrate.

7. The system of claim 1, wherein the substrate includes one or more portions associated with dielectric materials and wherein application of the temperature application component in accordance with the at least one trace pattern is characterized in non-uniform application of the specified temperature parameters to the substrate includes minimizing application of the temperature application component to the one or more portions associated with dielectric materials.

8. The system of claim 1, wherein the substrate includes one or more components mounted on the substrate and wherein application of the temperature application component in accordance with the at least one trace pattern is characterized in non-uniform application of the specified temperature parameters to the substrate includes minimizing direct application of the temperature application component to the components mounted on the substrate.

9. The system of claim 1, wherein the at least one trace pattern includes a symmetric pattern relative to an axis of the substrate.

10. The system of claim 1, wherein the at least one trace pattern includes an asymmetric pattern relative to an axis of the substrate.

11. A control system for causing a selective application of a temperature control component to a substrate, comprising:
one or more processing components that can execute executable instructions that cause the control system to:
obtain a specification of at least one trace pattern for positioning of the temperature application component along the substrate in accordance with the reflow grid array; and
execute a control program for causing application of the temperature application component in accordance with the at least one trace pattern, wherein application of the temperature application component in accordance with the at least one trace pattern is characterized in non-uniform application of specified temperature parameters to the substrate.

12. The system of claim 11, wherein the one or more processing components include at least one machine learned component for causing the application of the temperature application component according to the at least one trace pattern on the substrate.

13. The system of claim 11, wherein the at least one trace pattern corresponds to a single side of the substrate.

14. The system of claim 11, wherein the system configuration includes a reflow grid array on a plurality of substrates, wherein each individual substrate includes at least one trace pattern for positioning of the temperature application component along the substrate in accordance with the reflow grid array.

15. The system of claim 14, wherein individual trace patterns for the plurality of substrates are complimentary to adjacent substrates.

16. The system of claim 11, wherein the control unit is further operative to receive feedback regarding application of the temperature application component to designated portions of the substrate.

17. The system of claim 11, wherein application of the temperature application component in accordance with the at least one trace pattern is characterized in non-uniform application of the specified temperature parameters to the substrate includes minimizing application of the temperature application component to one or more identified portions of the substrate.

18. The system of claim 11, wherein the at least one trace pattern includes a symmetric pattern relative to an axis of the substrate.

19. The system of claim 11, wherein the at least one trace pattern includes an asymmetric pattern relative to an axis of the substrate.

20. A control method for application of temperature control components to a substrate comprising:
obtaining a specification of at least one trace pattern for positioning of the temperature application component along the substrate in accordance with the reflow grid array; and
executing a control program for causing application of the temperature application component in accordance with the at least one trace pattern, wherein application of the temperature application component in accordance with the at least one trace pattern is characterized in non-uniform application of specified temperature parameters to the substrate.

21. The system of claim 20, wherein executing the control program includes executing a machine learned algorithm for the application of the temperature application component according to the at least one trace pattern on the substrate.

22. The system of claim 20 further comprising receiving feedback regarding application of the temperature application component to designated portions of the substrate.

23. The system of claim 20, wherein application of the temperature application component in accordance with the at least one trace pattern is characterized in non-uniform application of the specified temperature parameters to the substrate includes minimizing application of the temperature application component to one or more identified portions of the substrate.
